(19) United States
(12) Patent Application Publication
(10) Pub. No.: US 2016/0247775 A1
(43) Pub. Date: Aug. 25, 2016

(54) CHIP PACKAGING STRCUTRE AND MANUFATURING METHOD THEREOF

(71) Applicant: Ali Corporation, Hsinchu (TW)

(72) Inventors: Yu-Ru Chang, Hsinchu (TW); Chih-Hung Kao, Hsinchu (TW); Chih-Ying Chen, Hsinchu (TW)

(21) Appl. No.: 14/732,189

(22) Filed: Jun. 5, 2015

(30) Foreign Application Priority Data
Feb. 25, 2015 (CN) 201510087080.3

(51) Int. Cl. H01L 23/00; H01L 21/54; H01L 21/56; H01L 23/367

(52) U.S. Cl. CPC H01L 24/13; H01L 23/367; H01L 21/54; H01L 21/56

(57) ABSTRACT

A chip packaging structure including a substrate, at least one chip, a plurality of conductive bumps, and an electrically insulating and thermally conductive material is introduced. The chip is disposed on a chip carrier, and the chip carrier is disposed on the substrate. The conductive bumps are disposed between the substrate and the chip carrier to electrically connect the substrate and the chip. The electrically insulating and thermally conductive material is disposed around and between the conductive bumps and covers the conductive bumps. Additionally, a manufacturing method of the chip packaging structure is also provided.

### CROSS-REFERENCE TO RELATED APPLICATION

This application claims the priority benefit of China application serial no. 201510087080.3, filed on Feb. 25, 2015. The entirety of the above-mentioned patent application is hereby incorporated by reference herein and made a part of this specification.

### BACKGROUND OF THE INVENTION

1. Field of the Invention

The invention relates to a chip packaging technology, and particularly relates to a chip packaging structure having an electrically insulating and thermally conductive material and a manufacturing method thereof.

2. Description of Related Art

In semiconductor industry, the production of integrated circuits (ICs) mainly includes three stages: wafer manufacturing, IC manufacturing, and IC packaging. The chip is manufactured through procedures of wafer manufacturing, circuit designing, photomask manufacturing, and wafer dicing etc. For each chip formed through wafer dicing, a molding compound may be used to cover the chip after a contact point on the chip is electrically connected with an external signal. The purpose of packaging is to prevent the chip from being influenced by moisture, heat and noise, and provide a medium for electrically connecting the chip and an external circuit. In this way, the steps of IC packaging are accomplished.

Through the continuous development of IC manufacturing technologies, integration of internal circuits of the chip keeps increasing. Thus, the number of transistors inside the internal circuits also increases continuously. Meanwhile, a cross-sectional area of conductive lines of the internal circuits gradually decreases. Thus, during operation, the chip may generate a significant amount of heat that makes the chip temperature increase or even makes the chip unable to function. Therefore, in addition to serving as a medium for external connection of chip signals, the chip packaging structure also needs to offer suitable protection and preferable heat dissipation performance.

In the conventional ball grid array (BGA) packaging products, it is common to solder the chip carrier on a printed circuit board (PCB) by adopting the surface mounting technology (SMT). However, the space between tin balls for soldering is not filled or covered with any material. Thus, for the BGA packaging products, heat generated by the chip can only be transmitted toward the printed circuit board through the tin balls and then discharged to the external environment through the printed circuit board. When the power of the chip is too high and too much heat is generated, an external heat dissipation device (e.g., a heat dissipation fin) needs to be disposed to enhance the heat dissipation and reduce the issue of over-heating of the chip. However, the external heat dissipation device takes a certain amount of space and imposes a limitation on an overall design of a case of an electronic device.

### SUMMARY OF THE INVENTION

The invention provides a chip packaging structure having an electrically insulating and thermally conductive material disposed between conductive bumps and covering the conductive bumps to improve heat dissipation of a chip.

The invention provides a manufacturing method of a chip packaging structure. An electrically insulating and thermally conductive material is formed between conductive bumps to cover the conductive bumps and increase an overall heat dissipation performance of the chip packaging structure.

An embodiment of the invention provides a chip packaging structure including a substrate, at least one chip, and a plurality of conductive bumps. The at least one chip is disposed on a chip carrier. In addition, the chip carrier is disposed on the substrate. The conductive bumps are disposed between the substrate and the chip carrier to electrically connect the substrate and the at least one chip. The electrically insulating and thermally conductive material is disposed in a space around and between the conductive bumps and covers the conductive bumps.

According to an embodiment of the invention, the substrate includes at least one through hole. The electrically insulating and thermally conductive material is inserted to cover the conductive bumps through the at least one through hole. And the at least one through hole is located below the at least one chip.

According to an embodiment of the invention, the at least one through hole is filled with the electrically insulating and thermally conductive material.

According to an embodiment of the invention, the chip packaging structure further includes injecting the electrically insulating and thermally conductive material from a side edge of the conductive bumps.

According to an embodiment of the invention, the chip packaging structure further includes an encapsulant. In addition, the encapsulant covers the at least one chip and is disposed on the chip carrier.

According to an embodiment of the invention, the chip packaging structure further includes a heatsink. In addition, the heatsink and the encapsulant contact with each other.

An embodiment of the invention provides a manufacturing method of a chip packaging structure. The method includes providing a substrate. The manufacturing method includes the following steps. At least one chip is disposed on a chip carrier, and the chip carrier and a plurality of conductive bumps are disposed on the substrate. In addition, the conductive bumps are disposed between the substrate and the chip carrier, and the conductive bumps electrically connect the substrate and the at least one chip. An electrically insulating and thermally conductive material is formed in a space around and between the conductive bumps. Moreover, the electrically insulating and thermally conductive material covers the conductive bumps.

According to an embodiment of the invention, the substrate includes at least one through hole, the through hole is located below the at least one chip. In addition, the step of forming the electrically insulating and thermally conductive material in the space around and between the conductive bumps includes: filling the electrically insulating and thermally conductive material into the space around and between the conductive bumps through the at least one through hole.

According to an embodiment of the invention, the electrically insulating and thermally conductive material is filled in the at least one through hole.

According to an embodiment of the invention, the step of forming the electrically insulating and thermally conductive material in the space around and between the conductive bumps includes: after disposing the conductive bumps between the substrate and the chip carrier, injecting the electrically insulating and thermally conductive material from a side edge of the conductive bumps.

According to an embodiment of the invention, the step of disposing the at least one chip on a chip carrier, and disposing the chip carrier and the conductive bumps on the substrate includes: forming the conductive bumps on a bottom surface of the chip carrier. Before disposing the chip carrier and the conductive bumps on the substrate, the electrically insulating and thermally conductive material is disposed on the substrate. The step of forming the electrically insulating and thermally conductive material in the space around and between the conductive bumps includes: inserting the conductive bumps formed on the bottom surface of the chip carrier into the electrically insulating and thermally conductive material.

According to an embodiment of the invention, the manufacturing method of the chip packaging structure further includes: before disposing the electrically insulating and thermally conductive material on the substrate, disposing a plurality of alignment marks on the substrate to align the at least one chip, the chip carrier, and the conductive bumps with the substrate.

According to an embodiment of the invention, the manufacturing method of the chip packaging structure further includes providing an encapsulant. The encapsulant covers the at least one chip and is disposed on the chip carrier.

According to an embodiment of the invention, the manufacturing method of the chip packaging structure further includes disposing a heatsink on the encapsulant. The heatsink and the encapsulant contact with each other.

Based on the above, in the chip packaging structure according to the embodiments of the invention, the conductive bumps are disposed between the chip carrier and the substrate, and the electrically insulating and thermally conductive material is disposed between the conductive bumps and covers the conductive bumps. Thus, with the electrically insulating and thermally conductive material being disposed, the chip may conduct heat to the substrate through the conductive bumps and the electrically insulating and thermally conductive material at the same time, so as to further enhance heat dissipation of the chip and thereby increase a reliability of the chip during operation. In addition, filling the electrically insulating and thermally conductive material into the space around and between the conductive bumps renders extra structural support between the chip carrier and the substrate, and stresses undertaken by the conductive bumps may be reduced. In this way, cracks of the conductive bumps may be prevented.

To make the above features and advantages of the invention more comprehensible, embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic view illustrating a chip packaging structure according to an embodiment of the invention.

FIGS. 2A and 2B are schematic views illustrating a chip packaging structure according to another embodiment of the invention.

FIGS. 3A and 3B are schematic views illustrating a chip packaging structure according to another embodiment of the invention.

FIG. 4 is a schematic view illustrating a chip packaging structure according to another embodiment of the invention.

FIG. 5 is a schematic view illustrating a chip packaging structure according to another embodiment of the invention.

FIG. 6 is a flowchart illustrating a manufacturing method of a chip packaging structure according to an embodiment of the invention.

FIG. 7 is a flowchart illustrating a manufacturing method of a chip packaging structure according to another embodiment of the invention.

FIG. 8 is a flowchart illustrating a manufacturing method of a chip packaging structure according to another embodiment of the invention.

FIGS. 9A, 9B, and 9C are schematic views illustrating a chip packaging structure according to another embodiment of the invention.

FIG. 10 is a flowchart illustrating a manufacturing method of the chip packaging structure shown in FIGS. 9A, 9B, and 9C.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

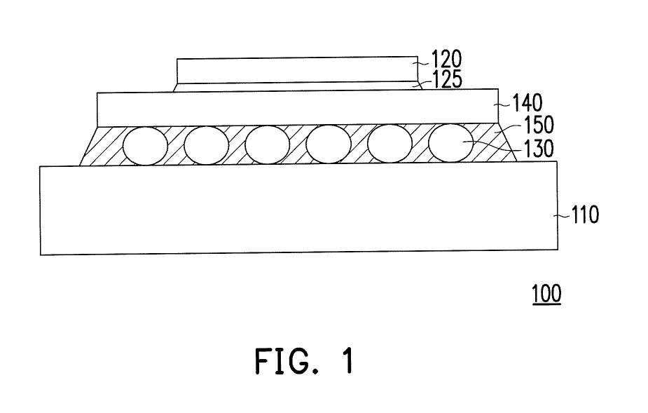

FIG. 1 is a schematic view illustrating a chip packaging structure according to an embodiment of the invention. Referring to FIG. 1, a chip packaging structure 100 includes a substrate 110, at least one chip 120, a plurality of conductive bumps 130, and an electrically insulating and thermally conductive material 150. In this embodiment, the chip 120 is disposed on a chip carrier 140, and the chip carrier 140 is disposed on the substrate 110. In addition, the conductive bumps 130 are disposed between the substrate 110 and the chip carrier 140 to electrically connect the substrate 110 and the chip 120. Moreover, the electrically insulating and thermally conductive material 150 is disposed in the space around and between the conductive bumps 130 and covers the conductive bumps 130. In this embodiment, the substrate 110 is a printed circuit board (PCB) or a flexible circuit board, for example. The conductive bumps 130 are solder bumps, copper pillars, copper stud bumps, or a golden stud bumps, etc., for example. In addition, the chip 120 may be connected to the chip carrier 140 through wire bonding or flip chip bonding, and an underfill 125 may be filled in between the chip 120 and the chip carrier 140. However, bonding between the chip 120 and the chip carrier 140 of this embodiment is not limited to those described above.

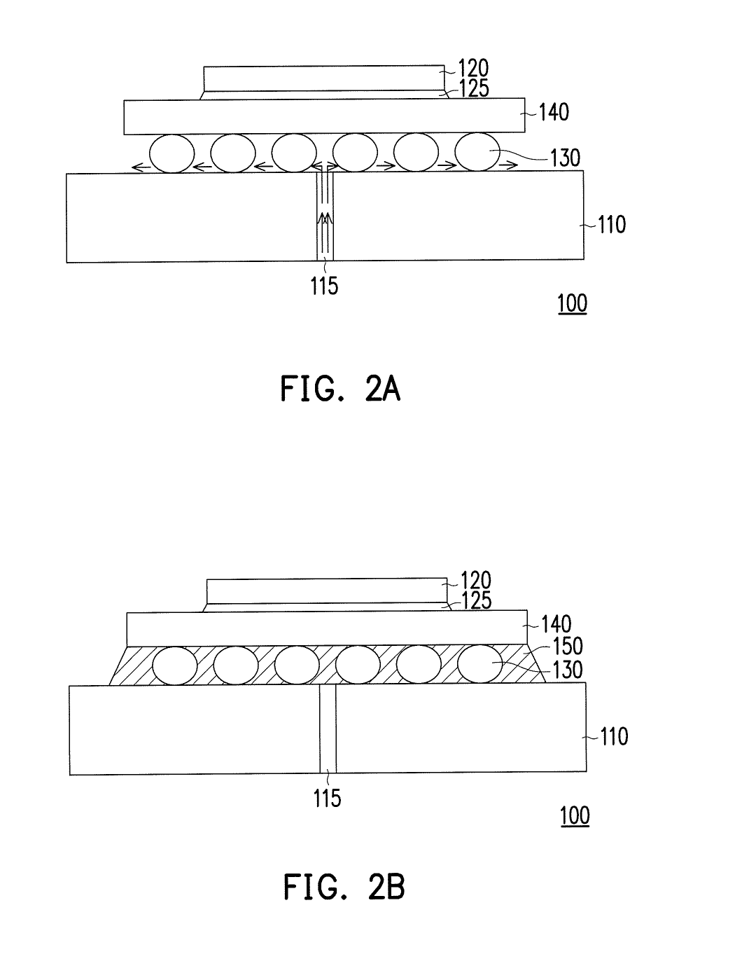

FIGS. 2A and 2B are schematic views illustrating a chip packaging structure according to another embodiment of the invention. Referring to FIG. 2A, in this embodiment, the substrate 110 may further include at least one through hole 115. In this way, the electrically insulating and thermally conductive material 150 may be filled between the conductive bumps 130 through the through hole 115. In this embodiment, the through hole 115 may be located in correspondence with a central position of the chip 120. In this way, the electrically insulating and thermally conductive material 150 filled through the through hole 115 may be evenly spread from the center of the chip carrier 140 toward edges (as indicated by arrow signs shown in FIG. 2A) through space between the substrate 110 and the chip carrier 140. When a thermal conductivity of the electrically insulating and thermally conductive material 150 assumed to be 3 W/mK for instance, compared with a configuration that the electrically insulating and thermally conductive material 150 is not filled in the space around and between the conductive bumps 130, a thermal impedance of the chip 120 is reduced by about 12% when the electrically insulating and thermally material 150 is filled into the space around and between all the conductive bumps 130 and covers all the conductive bumps 130 (as shown in FIG. 2B). In addition, by filling the electrically insulating and thermally conductive material 150 between the conductive bumps 130, a structural support between the chip carrier 140 and the substrate 110 is enhanced, and stresses undertaken by the conductive bumps 130 may be reduced. In this way, cracks of the conductive bumps 130 may be prevented.

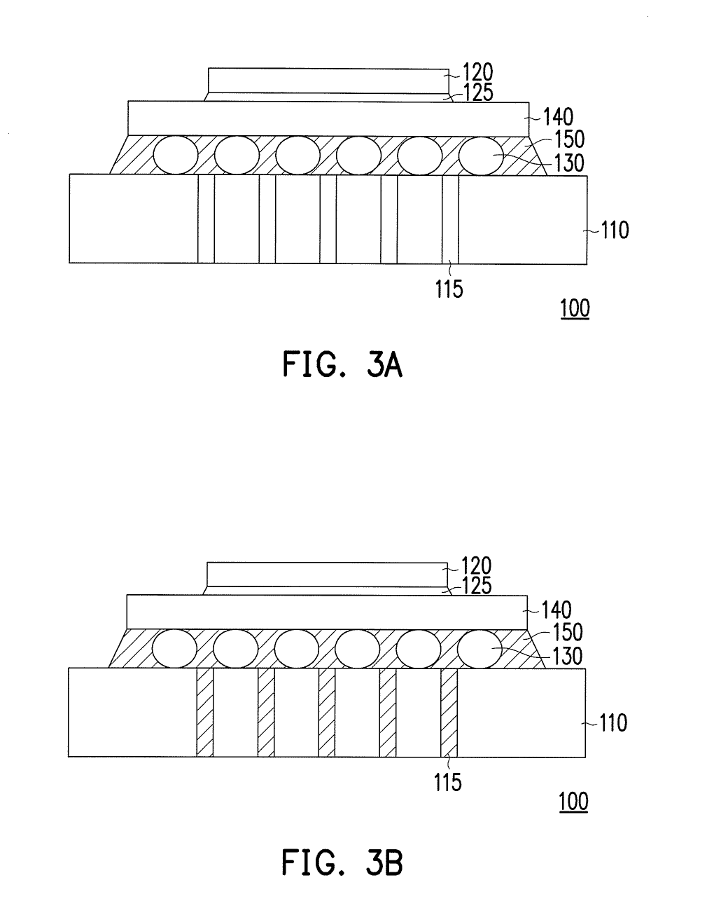

FIGS. 3A and 3B are schematic views illustrating a chip packaging structure according to another embodiment of the invention. Referring to FIG. 3A, in this embodiment, the number of the through hole 115 disposed in the substrate 110 may be plural, and the through holes 115 may be evenly distributed in the substrate 110 in correspondence with positions where the chip carrier 140 and the conductive bumps 130 are disposed. Thus, the electrically insulating and thermally conductive material 150 may be simultaneously filled through the through holes 115, so as to improve efficiency and speed of injecting the electrically insulating and thermally conductive material 150. It should be noted that, in the embodiment, in addition to being filled to cover the conductive bumps 130 through the through holes 115, the electrically insulating and thermally conductive material 150 may also be filled in the through holes 115 (as shown in FIG. 3B). In this way, heat generated by the chip 120 may be discharged to the external environment through the electrically insulating and thermally conductive material 150 in the through holes 115 in addition to being discharged through the substrate 110. Thus, heat dissipation is improved.

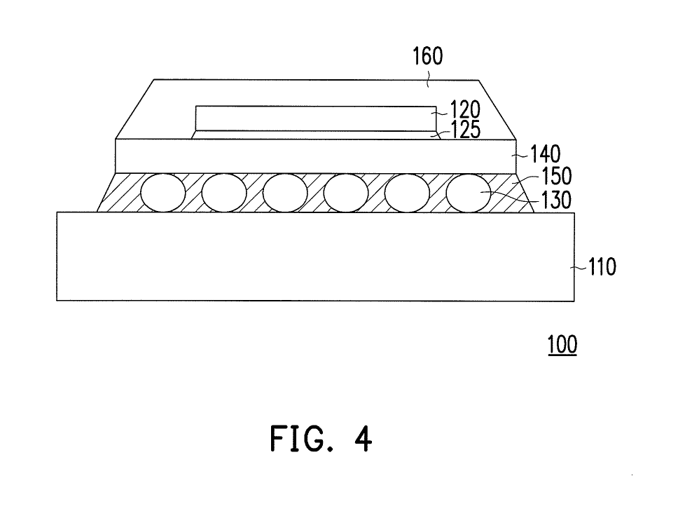

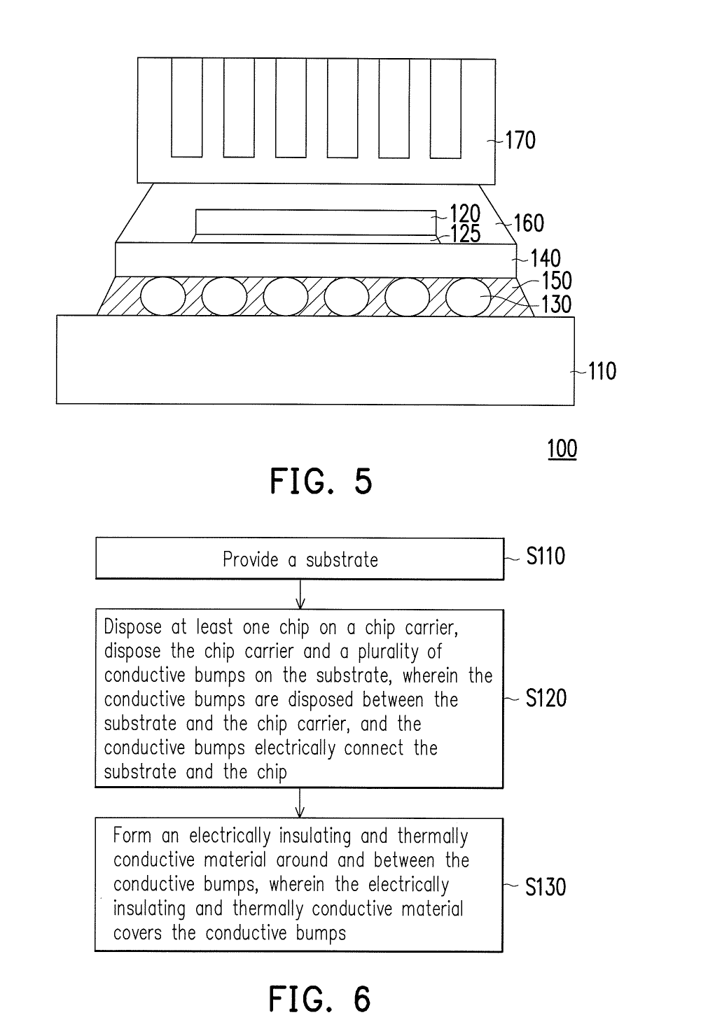

FIGS. 4 and 5 are respectively schematic views illustrating chip packaging structures according to other embodiments of the invention. Referring to FIG. 4, the chip packaging structure 100 further includes an encapsulant 160. In this embodiment, the encapsulant 160 covers the chip 120 and is disposed on the chip carrier 140 to prevent the chip 120 from being damaged by external force and from being polluted due to humidity and dust of the external environment. In addition, referring to FIG. 5, in another embodiment, a heatsink 170 may be additionally disposed above the encapsulant 160, and the heatsink 170 and the encapsulant 160 contact with each other. In this way, the chip 120 of this embodiment may also discharge heat through a heat discharging path formed by the encapsulant 160 and the heatsink 170 at the same time when discharging the heat to the external environment through the substrate 110. Accordingly, the effect of heat dissipation is enhanced.

It should be noted that the encapsulant 160 shown in FIG. 4 and the heatsink 170 disposed on the encapsulant 160 shown in FIG. 5 may also be respectively used in the chip packaging structure 100 shown in FIGS. 2A and 2B or FIGS. 3A and 3B. In this way, in addition to injecting the electrically insulating and thermally conductive material 150 into the space around and between the conductive bumps 130 and filling the through holes 115 with the electrically insulating and thermally conductive material 150 to improve the effect of heat dissipation of the chip packaging structure 100, the path formed by the encapsulant 160 and the heatsink 170 may further discharge the heat to additionally improve the effect of heat dissipation.

FIG. 6 is a flowchart illustrating a manufacturing method of a chip packaging structure according to an embodiment of the invention. Referring to FIGS. 1 and 6, in this embodiment, a manufacturing method of the chip packaging structure 100 includes providing the substrate (Step S110). Then, at least one chip 120 is disposed on the chip carrier 140, and the chip carrier 140 and the conductive bumps 130 are disposed on the substrate 110 (Step S120). Specifically, the conductive bumps 130 are disposed between the substrate 110 and the chip carrier 140, and the conductive bumps 130 electrically connect the substrate 110 and the chip 120. In addition, the manufacturing method of this embodiment includes forming the electrically insulating and thermally conductive material 150 in the space around and between the conductive bumps 130, and the electrically insulating and thermally conductive material 150 covers the conductive bumps (Step S130). Moreover, in this embodiment, the chip 120 may be connected to the chip carrier 140 through wire bonding or flip chip bonding, and the underfill 125 may be filled between the chip 120 and the chip carrier 140. For example, the underfill 125 may be cured through baking process and covers the bumps (not shown) between the chip 120 and the chip carrier 140 after being filled into the space between the chip 120 and the chip carrier 140, so as to prevent horizontal cracks of the bumps due to repetitive actions of thermal stresses of the chip 120 and the chip carrier 140.

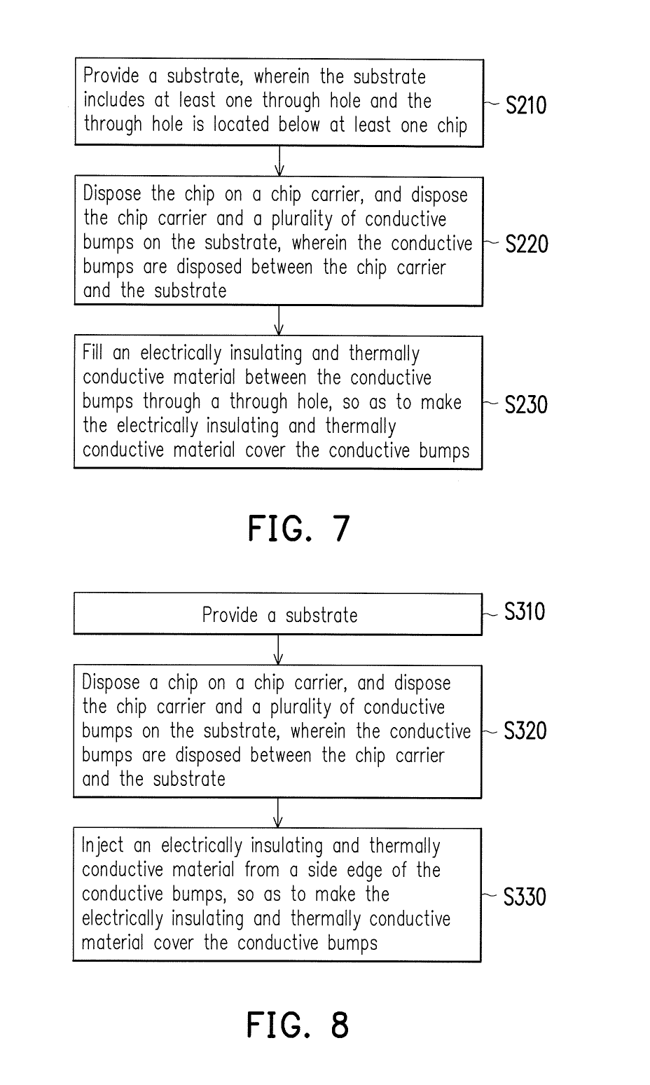

FIG. 7 is a flowchart illustrating a manufacturing method of a chip packaging structure according to another embodiment of the invention. Referring to FIGS. 2A, 2B, and 7, the manufacturing method of this embodiment includes providing the substrate 110 (Step S210). Said substrate 110 has at least one through hole 115, and the through hole 115 is located below the chip 120. In this embodiment, the position of the through hole 115 corresponds to the central position of the chip 120. Then, the chip 120 is disposed on the chip carrier 140, and the chip carrier 140 and the conductive bumps 130 are disposed on the substrate 110. Moreover, the conductive bumps 130 are disposed between the chip carrier 140 and the substrate 110 (Step S220). Then, as shown in FIGS. 2A and 2B, the electrically insulating and thermally conductive material 150 is injected into the space around and between the conductive bumps 130 through the through hole 115, for example, via a syringe. Afterwards, the electrically insulating and thermally conductive material 150 spreads from the central position to the edges of the chip carrier 140 along the space between the chip carrier 140 and the substrate 110, so as to cover the conductive bumps 130 between the chip carrier 140 and the substrate 110 (Step S230). In this embodiment, the through hole 115 located at the substrate 110 may be formed by laser drilling or mechanical drilling, and a diameter of the through hole 115 may correspond to a diameter of the syringe used to inject the electrically insulating and thermally conductive material 150. It should be noted that during the electrically insulating and thermally conductive material 150 spreading from the center to the edges of the chip carrier 140, gas existing between the chip carrier 140 and the substrate 110, such as air, may be pushed out toward the edges of the chip carrier 140. In this way, the electrically insulating and thermally conductive material 150 may be prevented from generating voids therein, and may completely cover the conductive bumps 130.

Moreover, in the manufacturing method of this embodiment, after the electrically insulating and thermally conductive material 150 is injected to completely cover the conductive bumps 130, a room-temperature curing process, a heating curing process, or other suitable curing process may be performed to cure the electrically insulating and thermally conductive material 150. After being cured, the electrically insulating and thermally conductive material 150 may fix the chip carrier 140, the conductive bumps 130, and the substrate 110 and enhance the structural support between the chip carrier 140 and the substrate 110. Meanwhile, stresses that the conductive bumps 130 undertake in both horizontal and vertical directions may decrease correspondingly.

Furthermore, referring to FIGS. 3A and 7 at the same time, the manufacturing method of this embodiment may further include uniformly forming multiple through holes 115 corresponding to the position of the chip carrier 140. In this way, the electrically insulating and thermally conductive material 150 may be simultaneously injected through the through holes 115, so as to increase speed and efficiency of the manufacturing process. Moreover, after finishing injecting the electrically insulating and thermally conductive material 150 to cover the conductive bumps 130, the electrically insulating and thermally conductive material 150 may be additionally filled into the through holes 115 (as shown in FIG. 3B), so as to establish more heat discharging paths in the substrate 110.

FIG. 8 is a flowchart illustrating a manufacturing method of a chip packaging structure according to another embodiment of the invention. Referring to FIGS. 8 and 1, the manufacturing method of this embodiment includes providing the substrate 110 (Step S310). Then, the chip 120 is disposed on the chip carrier 140, and the chip carrier 140 and the conductive bumps 130 are disposed on the substrate 110. Moreover, the conductive bumps 130 are disposed between the chip carrier 140 and the substrate 110 (Step S320). Afterwards, in this embodiment, the electrically insulating and thermally conductive material 150 may be injected into the space between the chip carrier 140 and the substrate 110 from the edge of one side of the conductive bumps 130, so as to make the electrically insulating and thermally conductive material 150 cover the conductive bumps 130 (Step S330). Specifically, the electrically insulating and thermally conductive material 150 may spread from the edge of the chip carrier 140 along the space between the chip carrier 140 and the substrate 110 due to the surface tension and the capillary action of the electrically insulating and thermally conductive material 150 until covering the overlapping area of the chip carrier 140 and the substrate 110. Thus, the electrically insulating and thermally conductive material 150 may be filled into spaces around and between the conductive bumps 130 and cover the conductive bumps 130. In this embodiment, due to the capillary action, it may prevent voids being generated in the electrically insulating and thermally conductive material 150 after filling of the electrically insulating and thermally conductive material 150. Moreover, in this embodiment, the chip packaging structure 100 may be disposed in a vacuum environment, so as to increase spreading speed of the electrically insulating and thermally conductive material 150 in the space between the chip carrier 140 and the substrate 110. The manufacturing method of this embodiment may skip the step of drilling a hole on the substrate 110 to form the through hole 115. In this way, a manufacturing process of the chip packaging structure 100 may be further simplified, and a manufacturing cost thereof may be reduced.

In the embodiments respectively shown from FIG. 6 to FIG. 8, ordering between the step of providing the substrate 110 and the step of disposing the chip 120 on the chip carrier 140 may be switched. The invention does not intend to impose a limitation on the ordering.

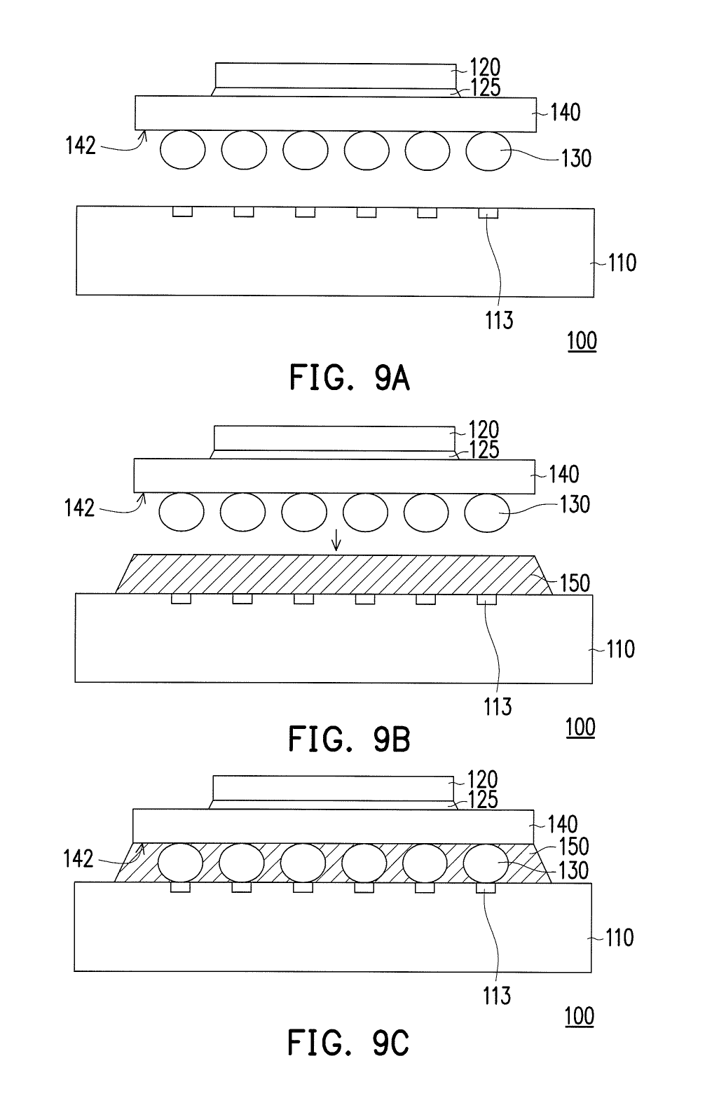

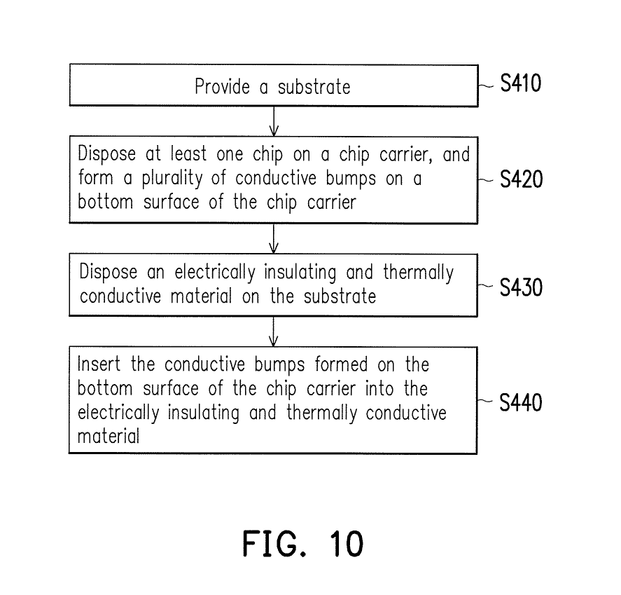

FIGS. 9A, 9B, and 9C are schematic views illustrating a chip packaging structure according to another embodiment of the invention. FIG. 10 is a flowchart illustrating a manufacturing method of the chip packaging structure shown in FIGS. 9A, 9B, and 9C. Referring to FIGS. 9A, 9B, 9C, and 10, compared with the previous embodiment, after the substrate 100 is provided (Step S410) and before the chip 120 and the chip carrier 140 are disposed on the substrate 110, the chip 120 is disposed on the chip carrier 140, and the conductive bumps 130 are disposed on a bottom surface 142 of the chip carrier 142 (Step S420) in the manufacturing method of this embodiment, as shown in FIG. 9A. Then, in this embodiment, a plurality of alignment marks 113 may be disposed on the substrate 110 in advance, in order to align the conductive bumps 130 on the bottom surface 142 of the chip carrier 140 with the substrate 110. Then, as shown in FIG. 9B, the electrically insulating and thermally conductive material 150 is directly disposed on the substrate 110 by coating, for example (Step S430). Following, the conductive bumps 130 formed on the bottom surface 142 of the chip carrier 140 are inserted downwardly (as indicated by the direction of the arrow sign in FIG. 9B) into the electrically insulating and thermally conductive material 150. In this way, the electrically insulating and thermally conductive material 150 completely covers the conductive bumps 130 and the space around and between the conductive bumps 130 (Step S440), as shown in FIG. 9C. In this embodiment, during the process that the conductive bumps 130 are inserted into the electrically insulating and thermally conductive material 150, an accuracy of alignment between the conductive bumps 130 and the substrate 110 is increased with the assistance of the alignment marks 113. In addition, the conductive bumps 130 may be fixed on the substrate 110 and covered by the electrically insulating and thermally conductive material 150 by pressing down the chip carrier 140 and heating to cure the electrically insulating and thermally conductive material 150.

In this embodiment, since the electrically insulating and thermally conductive material 150 is disposed on the substrate 110 in advance, the process of injecting the electrically insulating and thermally conductive material 150 and filling the space between the chip carrier 140 and the substrate 110 may be omitted, and uneven spreading of the electrically insulating and thermally conductive material 150 between the chip carrier 140 and the substrate 110 may be avoided. Accordingly, speed of coating or spreading of the electrically insulating and thermally conductive material 150 on the substrate 110 may be increased.

In view of the foregoing, in the above embodiments, by filling the electrically insulating and thermally conductive material into space around and between the conductive bumps and covering the conductive bumps, the heat impedance of the chip packaging structure relating to heat dissipation may be decreased, so as to increase the heat discharging paths, heat dissipation capability and reliability of the chip. Besides, due to the increase of the heat dissipation capability of the chip, external heat dissipation devices may be reduced and even omitted according to the invention. Accordingly, an overall thickness of the chip packaging structure may be reduced, so as to offer more flexibility in an overall design of a case of an electronic device. Moreover, with the electrically insulating and thermally conductive material being disposed, the strength of the structural support between the chip carrier and the substrate in the invention may be further increased. Meanwhile, with covering of the electrically insulating and thermally conductive material, the stresses undertaken by the conductive bumps in the vertical and horizontal directions are correspondingly reduced. Thus, cracks of the conductive bumps may be prevented, and an overall thermal resistance and stability of the chip packaging structure may be increased.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A chip packaging structure, comprising:
a substrate;
at least one chip, disposed on a chip carrier, wherein the chip carrier is disposed on the substrate;
a plurality of conductive bumps, disposed between the substrate and the chip carrier to electrically connect the substrate and the at least one chip; and
an electrically insulating and thermally conductive material, disposed in a space around and between the conductive bumps and covering the plurality of conductive bumps.

2. The chip packaging structure as claimed in claim 1, wherein the substrate comprises at least one through hole, the electrically insulating and thermally conductive material is inserted to cover the conductive bumps through the at least one through hole, and the at least one through hole is located below the at least one chip.

3. The chip packaging structure as claimed in claim 2, wherein the at least one through hole is filled with the electrically insulating and thermally conductive material.

4. The chip packaging structure as claimed in claim 1, wherein the electrically insulating and thermally conductive material is injected from a side edge of the conductive bumps.

5. The chip packaging structure as claimed in claim 1, further comprising an encapsulant, wherein the encapsulant covers the at least one chip and is disposed on the chip carrier.

6. The chip packaging structure as claimed in claim 5, further comprising a heatsink, disposed on the encapsulant, wherein the heatsink and the encapsulant contact with each other.

7. A manufacturing method of a chip packaging structure, comprising:
providing a substrate;
disposing at least one chip on a chip carrier, and disposing the chip carrier and a plurality of conductive bumps on the substrate, wherein the conductive bumps are disposed between the substrate and the chip carrier, and the conductive bumps electrically connect the substrate and the at least one chip; and
forming an electrically insulating and thermally conductive material in a space around and between the conductive bumps, wherein the electrically insulating and thermally conductive material covers the conductive bumps.

8. The manufacturing method of the chip packaging structure as claimed in claim 7, wherein the substrate comprises at least one through hole, the through hole is located below the at least one chip, and
the step of forming the electrically insulating and thermally conductive material in the space around and between the conductive bumps comprises:
filling the electrically insulating and thermally conductive material into the space around and between the conductive bumps through the at least one through hole.

9. The manufacturing method of the chip packaging structure as claimed in claim 7, wherein the electrically insulating and thermally conductive material is filled in the at least one through hole.

10. The manufacturing method of the chip packaging structure as claimed in claim 7, wherein the step of forming the electrically insulating and thermally conductive material in the space around and between the conductive bumps comprises:
injecting the electrically insulating and thermally conductive material from a side edge of the conductive bumps.

11. The manufacturing method of the chip packaging structure as claimed in claim 7, wherein the step of disposing the at least one chip on a chip carrier, and disposing the chip carrier and the conductive bumps on the substrate comprises:
forming the conductive bumps on a bottom surface of the chip carrier; and
disposing the electrically insulating and thermally conductive material on the substrate before disposing the chip carrier and the conductive bumps on the substrate, and
the step of forming the electrically insulating and thermally conductive material in the space around and between the conductive bumps comprises:
inserting the conductive bumps formed on the bottom surface of the chip carrier into the electrically insulating and thermally conductive material.

12. The manufacturing method of the chip packaging structure as claimed in claim 11, further comprising:
before disposing the electrically insulating and thermally conductive material on the substrate, disposing a plurality of alignment marks on the substrate to align the at least one chip, the chip carrier, and the conductive bumps with the substrate.

13. The manufacturing method of the chip packaging structure as claimed in claim 7, further comprising providing an encapsulant, wherein the encapsulant covers the at least one chip and is disposed on the chip carrier.

14. The manufacturing method of the chip packaging structure as claimed in claim 13, further comprising disposing a heatsink on the encapsulant, wherein the heatsink and the encapsulant contact with each other.
